(19) United States
(12) Patent Application Publication
(10) Pub. No.: US 2016/0240813 A1
(43) Pub. Date: Aug. 18, 2016

(54) ELECTRONIC COMPONENT AND METHOD FOR PRODUCING AN ELECTRONIC COMPONENT

(71) Applicant: OSRAM OLED GMBH, Regensburg (DE)

(72) Inventors: Philipp SCHWAMB, Regensburg (DE); Simon SCHICKTANZ, Regensburg (DE)

(21) Appl. No.: 15/022,553

(22) PCT Filed: Aug. 19, 2014
(86) PCT No.: PCT/EP2014/067686

§ 371 Date: Mar. 16, 2016

(30) Foreign Application Priority Data
Sep. 16, 2013 (DE) 10 2013 110 174.7

(51) Int. Cl. H01L 51/52; H01L 51/56

(52) U.S. Cl. CPC H01L 51/5246; H01L 51/5243; H01L 51/56

(57) ABSTRACT

The invention relates to an electronic component (1) with a substrate (2), on which an organic electronic functional area (3) is arranged, and a cover (4) which extends over the electronic functional area. Said cover is connected to the substrate by means of an electrically conductive solder layer (5). The invention also relates to a method for producing an electronic component.

The present disclosure relates to an electronic component and to a method for producing an electronic component.

One object to be achieved is to specify a novel, in particular improved, electronic component and respectively a novel, in particular improved, method for producing an electronic component.

This object is achieved by means of the subjects of the independent patent claims. Further advantageous configurations are evident from the following description and the dependent patent claims.

In accordance with one embodiment, an electronic component is specified comprising a substrate, on which an electronic functional region is arranged. The component preferably furthermore comprises a cover extending over the electronic functional region. The cover is connected to the substrate by means of an electrically conductive layer, for example a solder layer, which may contain or consist of a solder material. Hereinafter, features described in association with a solder layer may therefore also relate to an electrically conductive layer, without this layer having to be embodied as a solder layer.

By means of the solder layer, the substrate may be connected to the cover mechanically stably and preferably permanently. The cover, if appropriate in combination with the substrate, may thus protect the functional region, for example against the action of force, gases or liquids. By means of an electrically conductive solder layer, the cover and the substrate may be impermeably connected to one another in a simplified manner, for instance in comparison with electrically insulating glass solders which are often used for the connection of two glasses but require a complicated process implementation or may be used only for a small number of material combinations, or in comparison with plastic adhesive layers, which regularly exhibit a lower impermeability, in particular with respect to water, than electrically conductive solder layers.

The penetration of foreign influences, such as gas, liquid or moisture, for example oxygen, sulfur or water, into the component in the connection region between cover and substrate and the penetration thereof as far as the electronic functional region may be reduced or avoided by means of the electrically conductive solder layer. The electronic functional region may thus be reliably protected and the risk of malfunctions of the component may be reduced. Electrically conductive solder materials, such as metal solders or metal alloy solders, for example, are particularly suitable for forming a solder layer suitable for an impermeable connection of the substrate to the cover.

Organic electronic functional regions are regularly particularly sensitive toward environmental influences and, in order that they do not degrade very rapidly, must be encapsulated comparatively impermeably. An impermeable connection between the cover and the substrate that may be realized in a simple manner such as with the electrically conductive solder layer is particularly advantageous for this purpose.

An electrically conductive solder layer additionally has the advantage that the layer may participate in the electrical contacting of the component. Compared with electrically insulating connections, such as organic adhesives or glass solders, for instance, an electrically conductive solder layer may therefore perform a plurality of functions.

In one preferred configuration, between the solder layer and the cover or between the solder layer and the substrate, a connection layer is arranged, to which the solder layer is connected, for example directly. The connection layer for its part may again be connected, in particular directly, to the cover or the substrate. The connection layer is expediently connected to the respective connection partner mechanically stably.

The provision of a connection layer makes it possible to offer for the solder layer a material with which the solder material connects well. The degrees of freedom in the material selection for the substrate or the cover are thus increased since, in the material selection, it is not necessary to ensure that the solder layer connects well with the cover or with the substrate, rather the connection layer may be provided for this purpose. For the solder material of the solder layer, it is therefore possible to select a material which does not connect with the cover or the substrate as well as it does with the connection layer. The, preferably framelike, connection region in which the solder layer connects the cover and the substrate may be defined by means of the connection layer.

In one preferred configuration, the connection layer is arranged between the solder layer and the substrate, and a further connection layer is arranged between the solder layer and the cover. The solder layer is expediently arranged between the connection layer and the further connection layer and connected, preferably directly, to the respective connection layer.

If two connection layers are provided, this increases the degrees of freedom in the selection of the cover and in the selection of the substrate. At the same time, it is possible to use a solder layer which is particularly suitable for an impermeable connection. For the cover and/or the substrate it is possible to use, for example, a flexible or rigid configuration, electrically conductive or electrically insulating material, in each case with a coating or without a coating. If only one connection layer is provided, then the element, for example the cover or the substrate, arranged on that side of the solder layer which faces away from the connection layer is preferably itself composed of a material which connects well with the solder material of the solder layer.

Explanations further above and below concerning the connection layer may in particular also relate to the further connection layer.

In one preferred configuration, the connection layer is electrically conducive. The connection layer may be electrically conductively connected to the solder layer. The connection layer may participate in particular in the electrical contacting of the component, for example by virtue of the fact that it forms a conductive connection between the solder layer and the functional region or participates in such a connection.

In one preferred configuration, the solder material of the solder layer connects with the connection layer better than with the material that is offered on that side of the connection layer which faces away from it, for example material of the cover or of the substrate.

In one preferred configuration, the material of the connection layer connects with the material arranged on that side of the connection layer which faces away from the solder layer better than the material of the solder layer.

In one preferred configuration, the connection layer is suitable as a wetting layer for the solder material of the solder layer.

The wetting layer may be wettable well with the solder material of the solder layer in liquid form, in particular better than the material offered on that side of the connection layer which faces away from the solder layer, such as, for instance, the material of the cover or of the substrate.

In accordance with a further embodiment, a method for producing an electrical component is specified.

Firstly, a substrate is provided, on which an electronic functional region is arranged. Afterwards, a cover is provided. The cover and the substrate are arranged relative to one another such that the cover extends over the electronic functional region. In this case, an interspace is formed between the substrate and the cover, for example besides the functional region.

A liquid solder material is thereupon introduced into the interspace, such that the interspace is filled with liquid solder material in places, preferably only in places and/or circumferentially. The liquid solder material is preferably mechanically linked both to the cover and to the substrate.

Subsequently, the solder material may be hardened, for example by cooling, in order to form a solder layer, by means of which the cover is connected to the substrate. The component is thereupon completed.

A connection layer may be provided on the substrate and/or the cover, said connection layer defining the wetting region with the liquid solder material. Preferably, the wetting region of the substrate and/or of the cover with the solder material is restricted to the connection layer. The connection layers preferably overlap. Expediently, solder material is arranged throughout between the substrate and the cover only in the overlap region between the two connection layers.

The component described further above and below may be producible or produced by means of the method described. Features described further above and below for the component may accordingly also be used for the method, and vice versa.

If the solder material is already introduced in liquid form, steps for melting, for instance by means of a laser, a solder material introduced in the solid state between two elements are obviated. Separate hardening steps, such as, for example, by means of irradiation for instance using laser radiation and/or UV radiation, which are often necessary in the case of adhesives are also omitted since the solder material hardens in a simple manner by cooling. A separate aftertreatment is not necessary. Furthermore, the liquid solder material may be applied locally, such that the constituent components for the component are heated only locally. A hot process in which the component has to be heated over a large area, as in the case of glass soldering, for instance, is not necessary, and so the risk of heat-governed damage to the electronic functional region is reduced.

A more impermeable connection may be formed by means of the solder layer in comparison with plastic adhesives. Moreover, electrically conductive solder materials, in particular metal solders or metal alloy solders, are generally more cost-effective than special plastic adhesives.

In one preferred configuration, the solder layer has a side surface, preferably two opposite side surfaces. One side surface may face away from the electronic functional region. The other side surface may face the electronic functional region. The respective side surface may be embodied such that it is curved, for example curved convexly as seen from outside. At least the outer side surface of the solder layer is preferably curved. The curvature may be defined by the surface tension of the liquid or liquefied solder material of the solder layer. Alternatively, the side surface—the outer side surface or the inner side surface—or both side surfaces may be curved concavely.

In one preferred configuration, the liquid solder material is introduced into the interspace, preferably between the two connection layers, by means of bath soldering, selected wave or flow soldering, or dip soldering.

In one configuration the solder material of the solder layer contains or consists of a metal or an alloy comprising one or a plurality of metals.

In one preferred configuration, the material of the connection layer contains or consists of a metal or an alloy comprising one or a plurality of metals.

In one preferred configuration, the solder material is a soft solder. By way of example, the soft solder may contain tin and silver or tin and bismuth. Soft solders in general and among them in particular the solders mentioned are distinguished by a particularly low melting point. The risk of thermally governed damage to the functional region during soldering is thus reduced.

In one preferred configuration, the solder material of the solder layer is selected from the following group: BiSn, AgSn.

In one preferred configuration, the connection layer contains or consists of copper.

In one preferred configuration, the connection layer is directly connected to the cover or the substrate, respectively.

In one preferred configuration, the solder layer is impermeably connected to the connection layer. The connection may be gas-tight and/or liquid-tight. The connection may be hermetically impermeable. The hermetically impermeable connection may be so impermeable that the permeability of the connection to water is less than 10⁻¹ g/(m² d), preferably less than 10⁻³ g/(m² d), particularly preferably less than 10⁻⁶ g/(m² d), where d denotes a day. When mention is made further above and below of a hermetic element or a hermetic impermeable connection, that may be taken to mean that the respective element or the connection has a permeability to water which is lower than the value mentioned above.

In one preferred configuration, the connection layer is impermeably, preferably hermetically impermeably, connected to the cover or the substrate, respectively.

In one preferred configuration, the solder material of the solder layer and/or the material of the connection layer is selected so as to be suitable for forming at least part of a, preferably impermeable, in particular hermetically impermeable, encapsulation for the electronic functional region.

In one preferred configuration, the electronic component comprises an encapsulation, preferably a hermetic encapsulation, of the functional region. The following may participate in the encapsulation: the solder layer, the connection layer, the further connection layer, the cover and/or the substrate. The encapsulation may surround the functional region, preferably on all sides. The functional region is preferably arranged in an encapsulated interior of the component which is defined by the encapsulation.

In one preferred configuration, the solder layer and/or the connection layer extends around the electronic functional region in a framelike fashion, in particular as seen in a plan view of the functional region. The formation of an encapsulation is thus facilitated.

In one preferred configuration, the component comprises at least two electrodes for the electronic functional region. The electrodes may be part of the electronic functional region. The functional region may be electrically conductively connected to external terminals of the component by means of the electrodes. By means of the external terminals, the component may be electrically contacted, for example conductively connected to an external power source. The two electrodes are expediently separated from one another in such a way that no short circuit arises.

In one preferred configuration, the solder layer is electrically conductively connected to the electronic functional region. The solder layer may be electrically conductively connected to one of the electrodes. In this way, the external electrical contacting of the component may be carried out by means of the solder layer. The solder layer may serve as an external electrical terminal of the component.

In one preferred configuration, the solder layer is electrically insulated or isolated from one of the electrodes. The solder layer may be insulated or isolated from both electrodes or only one of the electrodes.

In one preferred configuration, the component comprises an electrically insulating layer. The electrical isolation or electrical insulation of the solder layer from one of the electrodes may be achieved by means of the electrically insulating layer. The electrically insulating layer is expediently arranged between the solder layer and a conductor connected to said electrode. An electrical isolation of the solder layer from one of the electrodes is particularly expedient if the solder layer is electrically conductively connected to the other electrode.

In one preferred configuration, the electrically insulating layer has anti-adhesion properties with respect to the solder material of the solder layer, for example in its liquid form. It is thus possible to prevent, in particular liquid, solder material from adhering to the electrically insulating layer during the production of the component. The solder material may thus be concentrated on the desired region, for instance the region of the connection layer, in a simplified manner.

In one preferred configuration, the connection layer is arranged between the electrically insulating layer and the solder layer.

In one preferred configuration, the electrically insulating layer is embodied as a thin-film layer.

In one preferred configuration, the electrically insulating layer extends over the functional region. The electrically insulating layer may extend in a manner starting from the substrate along one side surface of the functional region, over that side of the functional region which faces away from the substrate, again along another side surface of the functional region back to the substrate. In particular, the electrically insulating layer may be part of an additional encapsulation for the electronic functional region. The functional region may thus be protected by the electrically insulating layer as early as before the formation and also precisely during the formation of the encapsulation of the component. The electrically insulating layer may be cut out for forming electrical contact with the functional region.

In one preferred configuration, the electrically insulating layer is arranged between the substrate and the solder layer. The connection layer is expediently arranged between the electrically insulating layer and the solder layer. The connection layer may adjoin the electrically insulating layer. Starting from a region between the solder layer and the substrate, the electrically insulating layer may extend over the functional region and, on that side of the functional region which faces away from the starting point, may extend again between the solder layer and the substrate.

In one preferred configuration, the solder layer is arranged besides the functional region as seen in a plan view of the electronic functional region. The risk of damage to the functional region as a result of the solder layer, particularly during the process of applying the solder material in the liquid phase, may thus be reduced.

In one preferred configuration, the component is a, preferably organic, optoelectronic component, for example a light emitting diode such as an organic light emitting diode (OLED).

In one preferred configuration, the electronic functional region is an organic functional region. Organic materials are particularly sensitive to external influences, such as gases or moisture, and so a solder layer for the connection between cover and substrate is particularly advantageous for this purpose. “Organic functional region” may mean that at least the material crucial for the electronic function of the component, for example a light generating layer or layer sequence, contains or consists of an organic material. Not necessarily all of the materials in the functional region need be organic. Electrodes which contain or consist of an inorganic material, for example ITO, may be provided.

In one preferred configuration, only one or preferably no electrical terminal of the component is arranged, particularly as seen in plan view, besides a luminous area of the component, that is to say the area from which radiation emerges.

In one preferred configuration, besides the cover and/or the substrate as seen in a plan view of the cover and/or the substrate, no electrical terminal for electrically contacting the component is arranged on the cover and/or the substrate. The substrate and/or the cover may define the luminous area of the component.

In one preferred configuration, the substrate and the cover have the same dimensions. In particular, the substrate and the cover may have the same size. In the case of optoelectronic components, in particular radiation emitting components, a large luminous area without visible external contacting may thus be produced in a simplified manner. A plurality of components may also be arranged besides one another and form a continuous luminous area, without electrical terminals or the like being visible on the side of the luminous area.

In one preferred configuration, the solder layer projects laterally beyond the substrate and/or the cover. This is expedient particularly if the solder layer participates in the electrical contacting of the component, since then, by mechanically bringing the solder layer into contact with the solder layer of a further electronic component, preferably embodied such that it is of the same type, it is possible to produce an electrical connection between these components.

In one preferred configuration, the connection layer has a thickness of 10 nm or less.

In one preferred configuration, the connection layer has a significantly larger area than the solder layer.

In one preferred configuration, the connection layer extends over the electronic functional region. The connection layer may extend in particular in a manner starting from a region between the solder layer and the substrate along the substrate right over a side of the functional region facing away from the substrate and back again in the direction of the substrate as far as to a location between the solder layer and the substrate. Complex structuring of the connection layer may thus be avoided. The connection layer may be applied over the whole area or over almost the whole area.

In one preferred configuration, a free space is formed between the electronic functional region and the cover. The risk of damage to the functional region as a result of mechanical contact with the cover may thus be reduced. A protection layer, for example a mechanical protection layer, may be arranged between the free space and the electronic functional region. The protection layer may mold around the functional region.

In one preferred configuration, the cover is mechanically linked to the electronic functional region. In particular, preferably at least regionally there is then no free space between the electronic functional region and the cover. An intermediate layer may be arranged between the electronic functional region and the cover, said intermediate layer being connected to the cover. Expediently, the intermediate layer is also connected to the functional region. The intermediate layer may be an adhesion promoting layer. During the production of the component, the alignment of the substrate and the cover relative to one another may be simplified by means of the adhesion promoting layer since the substrate and the cover may be fixed in a manner already aligned with respect to one another by means of the adhesion promoting layer and the encapsulation may subsequently be effected by means of the solder layer, without the elements having to be held in a specific position and in a manner aligned relative to one another. The production method may thus be simplified.

Further features, advantages and expediencies will become apparent from the following description of the exemplary embodiments in conjunction with the figures.

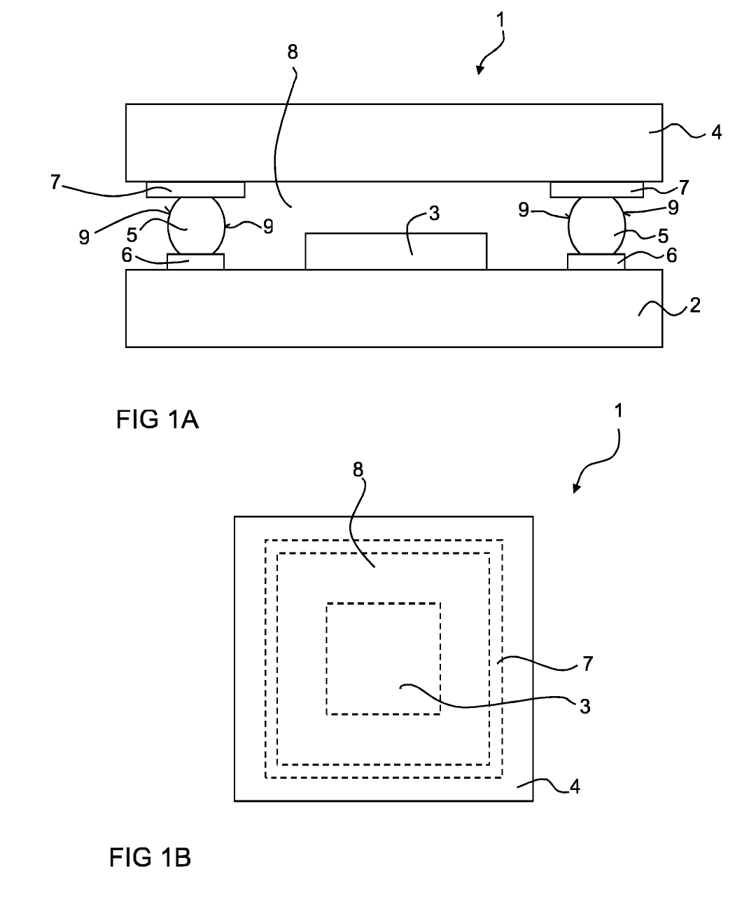

FIG. 1A shows a schematic sectional illustration of one exemplary embodiment of an electronic component and

FIG. 1B shows the associated plan view of the component.

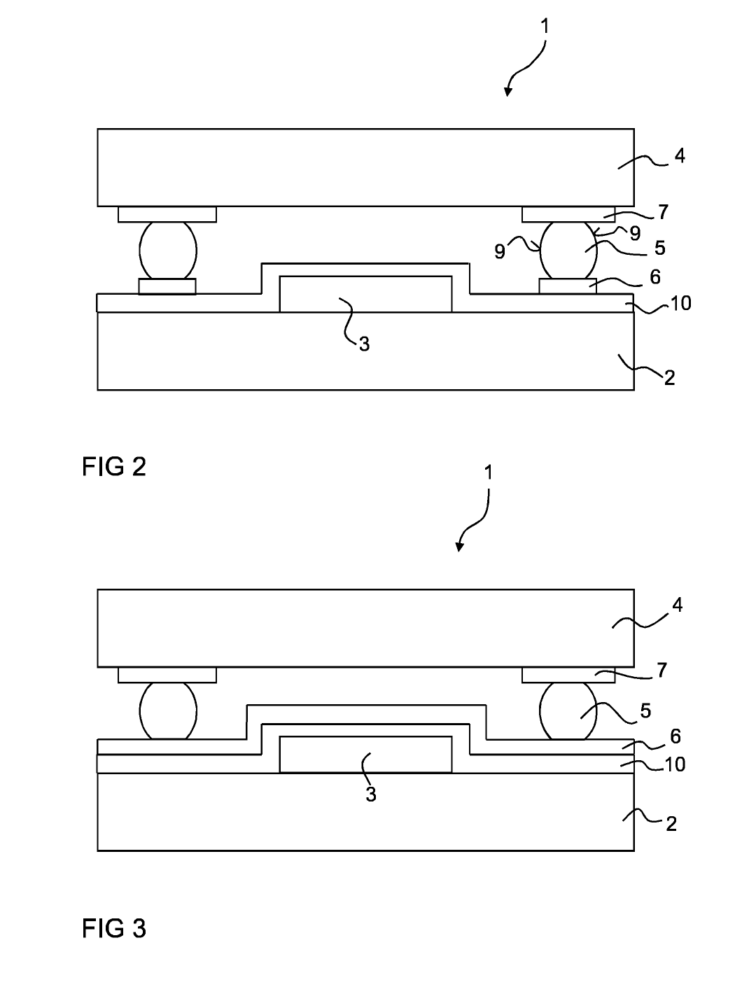

FIGS. 2 to 6 in each case show a schematic sectional illustration of a further exemplary embodiment of an electronic component.

FIG. 7 shows one exemplary embodiment of a method for producing an electronic component on the basis of a schematic view.

Elements that are identical, of identical type and act identically are provided with identical reference signs in the figures. Furthermore, individual elements are possibly illustrated with an exaggerated size in relation to other elements in order to afford a better understanding and so the illustration in the figures is not necessarily to scale.

FIG. 1A shows a schematic sectional illustration of one exemplary embodiment of an electronic component. FIG. 1B shows the associated plan view of the component, in particular a plan view of the cover.

The electronic component 1, for example an OLED, comprises a substrate 2. An electronic functional region 3 is arranged on the substrate 2, said electronic functional region expediently being carried by the substrate 2. The functional region 3 may be an organic functional region. The electronic functional region 2 may be arranged in a manner spaced apart from an edge of the substrate, for example centrally, on the substrate. The functional region 3 is preferably spaced apart circumferentially from the edge of the substrate. The component 1 furthermore comprises a cover 4. The cover 4 extends over the electronic functional region 3. The cover 4 may protect the electronic functional region 3 against harmful external influences, such as against mechanical loading, against gases and/or moisture. Alternatively or supplementarily, the substrate 2 may be designed to protect the functional region against harmful external influences, such as against mechanical loading, against gases, and/or against moisture. The cover 4 preferably completely covers the electronic functional region 3. The cover 4 may also extend over the substrate over a large area. In particular, the cover 4 may have the same or approximately the same dimensions as the substrate 2. The substrate 2 and the cover 4 are connected to one another mechanically stably, impermeably, for example liquid-tightly or gas-tightly, and preferably permanently. A solder layer 5 is arranged between the cover and the substrate. The substrate 2 is connected to the cover 4 by means of the solder layer 5.

A first connection layer 6 is arranged between the solder layer 5 and the substrate 2. The first connection layer 6 directly adjoins the substrate 2 and/or directly adjoins the solder layer 5. The connection layer 6 may produce a mechanically stable connection between the substrate 2 and the solder layer 5. Preferably, the solder material of the solder layer connects with the material of the connection layer better than with the material offered on the side of the substrate. The provision of the connection layer thus makes it possible to improve the mechanical linking of the solder layer to the substrate. Here, further above and below, “better connection” may encompass the fact that the still liquid solder material forms a smaller contact angle during the wetting of the connection layer than during the wetting of the material offered on the part of the substrate. Wetting with the solder material may therefore be improved by the connection layer. Alternatively or supplementarily, the connection with the connection layer may be formed faster than with the material offered on the part of the substrate.

Furthermore, a second connection layer 7 is arranged between the cover 4 and the solder layer 5. The connection between the solder layer and the cover may thereby be improved in accordance with the above explanations concerning the connection to the substrate. The solder layer 5 and/or the cover 4 expediently directly adjoin(s) the second connection layer 7.

The solder layer 5, the first connection layer 6 and/or the second connection layer 7 may extend completely around the electronic functional region 3 as seen in plan view (see FIG. 1B). The solder layer 5 may be arranged in particular besides the electronic functional region 3. In other words, a solder frame may run around the functional region.

The solder layer 5 together with the substrate 2 and the cover 4 defines an interior 8 of the component 1. The interior 8 may cover the electronic functional region 3 and may be arranged in particular between the cover and the functional region 3 and/or between side surfaces of the functional region 3 and the solder layer 5.

The electronic functional region 3 is encapsulated impermeably, in particular hermetically impermeably, with respect to the surroundings by the substrate, the cover 4, the solder layer 5, the first connection layer 6 and the second connection layer 7. The functional region 3 may thus be efficiently encapsulated against harmful external influences such as gases, for example oxygen or sulfur, or moisture, which could penetrate into the interior 8 without corresponding encapsulation. The respective materials or elements are expediently designed or chosen for the encapsulation such that an impermeable, in particular hermetically impermeable, encapsulation of the electronic functional region 3 is achieved. The respective element itself is expediently impermeable, in particular hermetically impermeable. The connection between the respective elements may also be impermeable, in particular hermetically impermeable. Organic functional regions are for example highly sensitive to moisture, and so an impermeable encapsulation of the functional region may significantly increase the lifetime of the component 1.

The provision of the respective connection layer 6, 7 makes it possible to select the substrate 2 or the cover 4 comparatively freely, without having to take account of the connection properties with the solder material of the solder layer 5. The good connection or wetting with the solder material of the solder layer 5 is ensured by the respective connection layer 6, 7. If a material which connects well with the solder material of the solder layer 5 is already offered by the substrate and/or the cover, then one or in the extreme case even both connection layers may be dispensed with. At least one connection layer is advantageous, since in general metals connect particularly well with solder materials, but metals often absorb radiation, which is disadvantageous, of course, for an OLED in which radiation couples out through the substrate or the cover. Preferably, therefore, a connection layer is provided on that side of the solder layer 5 which faces a coupling-out side of the component 1. If the component has two coupling-out sides, two connection layers are advantageous.

The substrate 2 and/or the cover 4 may be embodied as rigid or flexible, for example as a film, electrically conductive, for example composed of conductive material, such as a metal, or electrically insulating, for example composed of electrically insulating material, such as a plastic or a glass. By way of example, the substrate and/or the cover may comprise or consist of a metal film, in particular a copper film. The substrate 2 and/or the cover 4 may furthermore comprise or consist of a plastic film. The respective film, for example the plastic film, may be provided with an additional barrier layer that preferably increases the impermeability of the substrate 2 and/or of the cover 4. The substrate 2 and/or the cover 4 may furthermore contain or consist of a glass layer.

If substrate 2 and cover 4 are embodied in a flexible fashion, then in particular the entire component may be embodied in a flexible fashion, thereby increasing the possibilities for use of a component. The component may be curved for example for the application.

By way of example, soft solder materials are appropriate for the solder material of the solder layer 5. In particular, the solder material of the solder layer 5 may be selected from the following group: AgSn, BiSn.

By way of example, copper is suitable for the material of the respective connection layer 6, 7. Copper connects particularly well with soft solders and in particular with the solders expediently mentioned above.

Furthermore, the respective connection layer 6, 7 may be embodied as a wetting layer for the solder material of the solder layer 5, such that liquid solder material wets the respective connection layers 6, 7 well. This has advantages when applying the solder material from the liquid phase (in this respect, cf. the description of the associated method further below). If copper, for example, is offered to the solder material of the solder layer on the substrate side or on the cover side, a connection layer may be dispensed with. Bath soldering, wave or flow soldering, in particular selective wave soldering such as mini-wave soldering, or dip soldering may be used for the soldering process.

The respective connection layer may have a thickness of 10 nm or less. Even such small thicknesses are sufficient for a good linking of the solder layer. The respective connection layer may be applied for example by means of vapor deposition, for example by thermal evaporation in a vacuum, or sputtering.

A width of the respective connection layer 6, 7 and/or of the solder layer 5 is expediently chosen such that the functional region 3 or the interior 8 is encapsulated impermeably. By way of example, the solder layer and/or the respective connection layer may have a width that is greater than 10 μm for example is up to 100 μm or more than 100 μm. A hermetic impermeability may be achieved, if appropriate, even with such small widths. The width may be up to 1 mm or up to 2 mm.

The solder layer 5 has one, preferably two, for example opposite, side surfaces 9. One side surface 9 is arranged on that side of the solder layer 5 which faces away from the functional region 3. A further side surface 9 is arranged on that side of the solder layer 5 which faces the functional region 3. The respective side surface may be curved, as illustrated. The respective side surface is preferably curved convexly as seen from outside. The curvature of the side surface may be obtained by the introduction of the liquid solder material and in particular on account of the surface tension of the solder material.

In the exemplary embodiment illustrated, the first connection layer 6, the solder layer 5 and/or the second connection layer 7 are/is offset inward relative to an edge of the substrate 2 and/or the cover 4. The risk of damage to the encapsulation as a result of external action on the solder layer or the respective connection layer may thus be avoided or at least reduced.

The electrical contacting of the component 1 is not always illustrated explicitly in the exemplary embodiments, for reasons of clarity. However, the component 1 expediently comprises two external electrical terminals. Each of said terminals may be electrically conductively connected to a separate electrode of the electronic functional region 3 (not illustrated explicitly). The conductive connections between the respective terminal and the functional region are expediently electrically isolated from one another in order to avoid a short circuit.

By means of the external terminals, the component may be electrically contacted, for example conductively connected to an external power source. The two electrodes are expediently separated from one another in such a way that no short circuit arises.

In one configuration, the solder layer 5 is electrically conductively connected to the electronic functional region. The solder layer 5 may be electrically conductively connected to one of the electrodes. In particular, in this way, the external electrical contacting of the component 1 may be effected by means of the solder layer 5. The solder layer may serve in particular as an external electrical terminal of the component.

In one configuration, the solder layer 5 is electrically insulated or isolated from one of the electrodes. The solder layer 5 may be insulated or isolated from both electrodes.

In one configuration, an electrically conductive connection between an external terminal and one of the electrodes extends through the substrate 2. Said electrode is expediently the one which is not connected to the solder layer 5 if such an electrode connected to the solder layer is provided. The extending of the conductive connection through the substrate 2 may be produced for example by the substrate being selected as electrically conductive. In that case, the solder layer is expediently electrically insulated from the substrate, for example by an electrically insulating layer (see further below). Alternatively, an electrically insulating substrate 2 may be used and a potential feedthrough through the substrate may be provided, for example in the form of a via filled with conductive material which electrically contacts an electrode of the functional region arranged on that side of the substrate which faces the electronic functional region. Furthermore, the electrically conductive connection to both electrodes may be effected through the substrate 2. If the substrate 2 is conductive, then a conductor material insulated from the substrate in a via through the substrate is expediently provided for the second electrode. In the case of an insulating substrate 2, two vias separated from one another may be provided. Furthermore, the electrically conductive connection to one of the electrodes may extend between the solder layer 5 and the substrate 2 or the cover 4 through by way of the region of the solder layer, and preferably out of the encapsulated region of the component 1. Alternatively or supplementary to the substrate 2, the contacting may, of course, also be effected through the cover 4, which for this purpose may have one or a plurality of electrical potential feedthroughs. The above explanations concerning the substrate 2 therefore correspondingly apply to the cover 4. One or a plurality of potential feedthroughs may also run between the solder layer 5 and the cover 4 or between the solder layer 5 and the substrate 2.

FIG. 2 shows an illustration of a further exemplary embodiment of an electronic component on the basis of a schematic sectional view.

The component 1 substantially corresponds to the component described in association with FIGS. 1A and 1B. In contrast thereto, an electrically insulating layer 10 is provided in the exemplary embodiment in accordance with FIG. 2. The layer 10 is arranged between the first connection layer 6 and the substrate 2. Accordingly, the electrically insulating layer 10 may electrically isolate the first connection layer 6 and the substrate 2 from one another. For the case where the connection layer 6 or the solder layer 5 connected thereto and the substrate 2 are connected to different electrical potentials, a short circuit of the component may be avoided in this way. The electrically insulating layer 10 therefore makes it possible to increase the degrees of freedom in the selection of the contacting for the electronic component. In particular, the solder layer 5, for example in the case of an electrically conductive substrate 2 or some other electrically conductive element which is arranged on the side of the insulating layer 10 facing away from the solder layer 5 and which is at a different potential than the solder layer 5 during the operation of the component 1, may participate in the electrical contacting in a simplified manner.

The electrically insulating layer 10 may extend over the substrate 2 over a large area, in particular over the whole area. Preferably, the electrically insulating layer 10 extends not only between the first connection layer 6 and the substrate 2, but also over the electronic functional region 3 of the component 1. The electrically insulating layer 10 may be deposited over the whole area on the substrate 2 before the connection layer 6 is applied. The electrically insulating layer 10 may accordingly also protect the functional region 3, specifically before the cover 4 and the solder layer 5 are actually provided. The electrically insulating layer 10 may accordingly provide a pre-encapsulation of the functional region 3.

The electrically insulating layer 10 may contain for example a silicon oxide, a silicon nitride, an aluminum oxide, a zinc oxide, a zirconium oxide, a titanium oxide, a hafnium oxide, a lanthanum oxide, or a tantalum oxide.

Materials mentioned above, in particular the oxides, such as aluminum oxide, may have anti-adhesion properties with regard to the solder material of the solder layer 5, such that the electrically insulating layer 10 may advantageously be embodied as a solder anti-adhesion layer.

The electrically insulating layer 10 may be embodied as thin-film encapsulation of the electronic functional region. It may have a thickness of 10 μm or less, preferably of 1 μm or less. The thin-film encapsulation may comprise at least one or a plurality of thin layers which are applied on the electrodes and the organic functional layer stack by means of a deposition method, preferably by means of a chemical gas deposition method and/or an atomic layer deposition method. An encapsulation embodied as a thin-film encapsulation is understood to mean in the present case, for example, a device suitable for forming a barrier with respect to atmospheric substances, in particular with respect to moisture and oxygen, and/or with respect to further damaging substances such as, for instance, corrosive gases, for example hydrogen sulfide. In other words, the thin-film encapsulation may be embodied in such a way that at most very small proportions of atmospheric substances may penetrate through it. In the case of the thin-film encapsulation, this barrier effect may substantially be produced by barrier layers and/or passivation layers which are embodied as thin layers and which are part of the encapsulation. The layers of the encapsulation generally have a thickness of less than or equal to a few 100 nm. In particular, the thin-film encapsulation may comprise or consist of thin layers which are responsible for the barrier effect of the encapsulation. The thin layers may be applied for example by means of an atomic layer deposition (ALD) method or molecular layer deposition (MLD) method. Suitable materials for layers of the encapsulation are, for example, aluminum oxide, zinc oxide, zirconium oxide, titanium oxide, hafnium oxide, lanthanum oxide, tantalum oxide. Preferably, the encapsulation comprises a layer sequence having a plurality of the thin layers, each having a thickness of between 1 atomic layer and a few 100 nm.

For forming electrical contact with that side of the electronic functional region 3 which faces away from the substrate 2, the electrically insulating layer 10 may be cut out (not illustrated explicitly in FIG. 2). In the region in which the electrically insulating layer 10 is cut out, a connection conductor layer may be arranged, which extends from the cutout along the electrically insulating layer 10 to the solder layer 5 and is electrically conductively connected to the latter, if appropriate by means of the first connection layer 6. In this way, the solder layer 5 may participate in the electrical contacting of the component 1 and, if appropriate, may even form an external electrical terminal of the component. Alternatively, the external electrical terminal may be formed by means of the cover 4, which is electrically conductively connected to the solder layer 5, or by means of a suitable potential feedthrough through the cover. The other external terminal may be formed by the substrate 2, for example by means of an electrically conductive substrate.

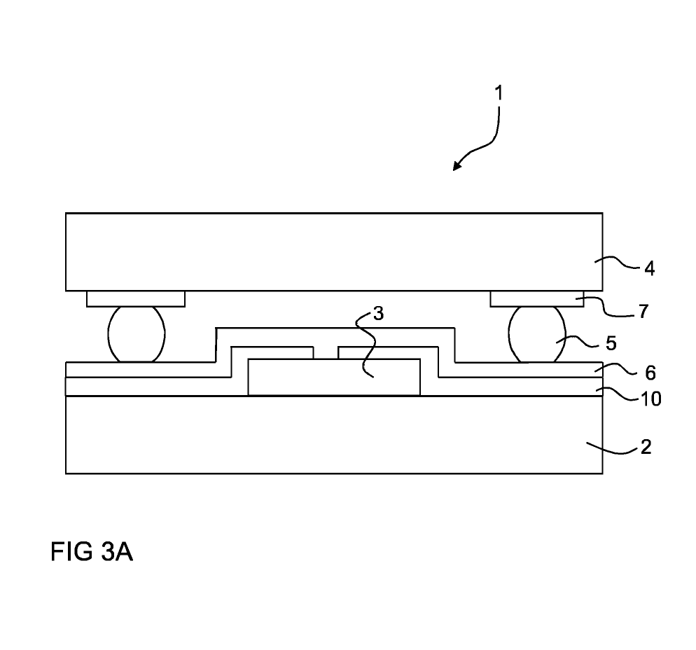

FIG. 3 shows a further exemplary embodiment of an electronic component on the basis of a schematic sectional view.

The component in accordance with FIG. 3 substantially corresponds to that illustrated in FIG. 2. In contrast thereto, the first connection layer 6 extends over the substrate 2 over a large area, in particular over the whole area. The connection layer 6 may be embodied in particular as a continuous layer in plan view, that is to say a layer that is not cut out or is not structured. The connection layer 6 may extend over the electronic functional region 3. A structuring or a structured application of the connection layer which may be necessary in other exemplary embodiments described may thus be avoided.

Alternatively or supplementarily, the second connection layer 7 may be arranged over a large area, in particular over the whole area, on the cover.

If the electrically insulating layer 10 is cut out for forming the contact with the electronic functional region 3 then the connection layer 6 may extend into the cutout and produce the electrical connection between the solder layer 5 and the electronic functional region 3. A corresponding exemplary embodiment is illustrated in FIG. 3A.

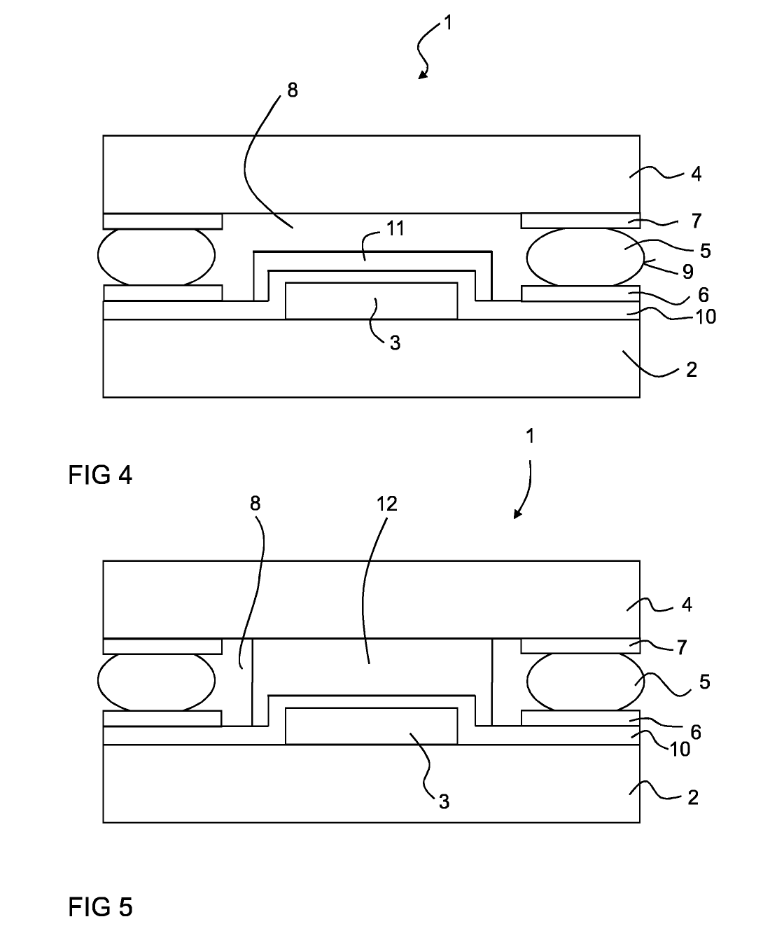

FIG. 4 shows a further exemplary embodiment of an electronic component on the basis of a schematic sectional view.

The component substantially corresponds to the component 1 shown in FIG. 2. In contrast thereto, the first connection layer 6, the second connection layer 7 and/or the solder layer 5 is arranged nearer to the edge of the substrate 2 and/or the cover 4. The outer side surface 9 of the solder layer 5 may project or protrude beyond the substrate 2 or the cover 4. The first connection layer, the second connection layer and the solder layer may be arranged in particular such that a connection region of the solder layer 5 to the respective connection layer 6, 7, the cover 4 or the substrate 2, respectively, is arranged in the overlap region of the solder layer 5 with the substrate 2 or the cover 4, respectively, but the side surface 9 of the solder layer projects beyond a side surface of the substrate 2 and/or of the cover 4 at least regionally.

Furthermore, in contrast to the exemplary embodiment in accordance with FIG. 2, a mechanical protection layer 11 is provided. The protection layer 11 is arranged so that it mechanically protects the electronic functional region 3. Compared with the comparatively thin electrically insulating layer, this layer may be mechanically stabler, in particular rigid, and thus prevent mechanical force actions on the electronic functional region in an improved manner. The mechanical protection layer 11 may be a plastic layer. The mechanical protection layer may be an epoxy or acrylate layer. The protection layer may be UV or thermally curable or cured. Two-component-curing material systems and pressure sensitive adhesives (PSAs) are also appropriate for the protection layer.

The protection layer 11 may protect the functional region 3 against mechanical force action, for example as a result of undesired contact with the cover 4, for instance during the production of the component 1 or during the operation of the component.

The protection layer 11 is expediently arranged such that a free space is left between the cover and that side of the protection layer which faces away from the electronic functional region 3. The mechanical protection layer 11 is expediently spaced apart, preferably circumferentially spaced apart, from the solder layer 5. A possible flexibility of the entire component 1 is thus also not impaired, or is only slightly impaired, by a rigid protection layer 11.

FIG. 5 shows a further exemplary embodiment of an electronic component on the basis of a schematic sectional view. The component in accordance with FIG. 5 substantially corresponds to the component described in association with FIG. 4. In contrast to the component in accordance with FIG. 4, no mechanical protection layer is provided. Rather, an adhesion promoting layer 12 is provided. The adhesion promoting layer 12 extends between the cover 4 and the substrate 2. The cover 4 may be fixed to the substrate 2 by means of the adhesion promoting layer 12. This may facilitate the introduction of a liquid solder material between the connection layers 6, 7. The adhesion promoting layer 12 may be composed of adhesive. The cover 4 and the substrate 2 may therefore already be mechanically connected to one another before the solder layer 5 is formed.

The adhesion promoting layer 12 may extend over the electronic functional region 3 and in particular preferably simultaneously serve as a mechanical protection layer for the electronic functional region. The adhesion promoting layer 12 expediently directly adjoins the cover 4. The interior 8 may run between adhesion promoting layer 12 and solder layer 5. The adhesion promoting layer 12 may be spaced apart circumferentially from the solder layer 5. The materials specified above for the protection layer 11 are also suitable for the adhesion promoting layer 12.

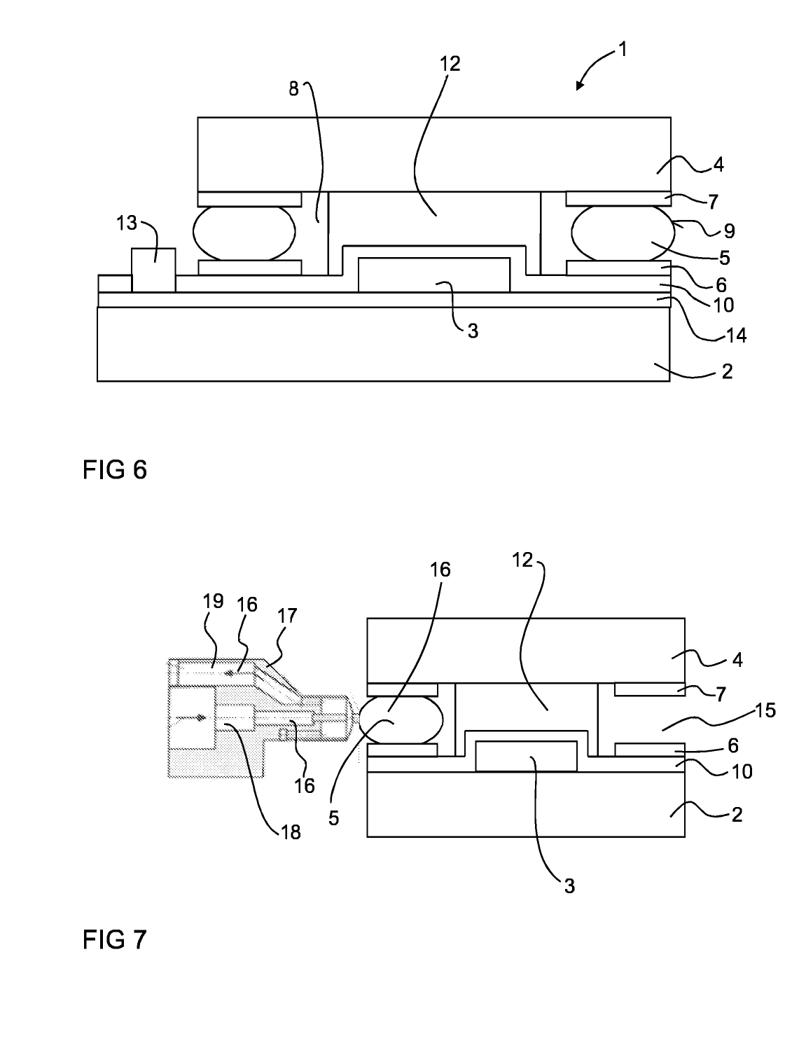

FIG. 6 shows a further exemplary embodiment of an electronic component on the basis of a schematic sectional view. The component in accordance with FIG. 6 substantially corresponds to the component described in association with FIG. 5. In contrast thereto, an external electrical terminal 13 is provided on the substrate 2 besides the cover 4 as seen in a plan view of the substrate, said external electrical terminal being electrically conductively connected to that side of the electronic functional region 3 which faces the substrate 2. For this purpose, an electrically conductive layer 14 is provided, which is arranged between the electrically insulating layer 10 and the substrate 2 and between the substrate and the electronic functional region 3. The external electrical terminal 13 preferably extends through the electrically insulating layer 10 as far as the electrically conductive layer 14 and is connected thereto. In the case illustrated, the substrate 2 may be electrically insulating since it does not have to be used for contacting. If an electrically conductive substrate is used, an external terminal is expediently provided on that side of the substrate which faces away from the electronic functional region 3. The layer 14 may then be dispensed with. Likewise, the external terminal 13 arranged on that side of the substrate which faces the cover is then expediently dispensed with since the area of the component would then be enlarged unnecessarily and, in particular, the formation of a large-area homogeneous lighting device comprising a plurality of close packed electronic components arranged besides one another would remain more difficult since no radiation power emerges from the OLED components in the region in which the external terminal 13 is provided.

FIG. 7 schematically illustrates one exemplary embodiment of a method for producing an electronic component on the basis of a schematic sectional view. The following explanation is given with regard to a component in accordance with FIG. 5 which is produced by means of the method. However, the method is suitable, of course, for all components described herein.

Firstly, the substrate 2 is provided, on which the electronic functional region 3 is arranged. The connection layer 6 is also already arranged on the substrate 2 and the electrically insulating layer 10 is arranged between the connection layer 6 and the substrate. Furthermore, a cover 4 is provided, on which the second connection layer 7 is arranged. The cover and the substrate are arranged relative to one another such that the connection layer 6 and the second connection layer 7 face one another and overlap at least regionally. In this position, the cover and the substrate are fixed by means of the adhesion promoting layer 12. The overlap region of the connection layers 6 and 7 preferably defines the connection region in which the cover and the substrate may be connected by means of a solder layer. An interspace 15 is formed between the connection layers 6, 7. A liquid solder material, for example one of the materials mentioned, is introduced into the interspace 15. The liquid solder material 16 wets the connection layers 6, 7. Adhesion of the solder material 16 to the electrically insulating layer 10 is advantageously avoided if the latter is embodied as a solder anti-adhesion layer. After the liquid solder material has cooled and hardened, it forms the solder layer that connects the cover 4 and the substrate 2 to one another.

In the present exemplary embodiment, selective wave soldering, in particular mini-wave soldering, is used for introducing the liquid solder material 16 into the interspace 15. In this case, a nozzle 17 may be provided, in which an inflow channel 18 and an outflow channel 19 for guiding the liquid solder material 16 are defined. The inflow channel 18 is connected to a solder bath (not illustrated). Solder material from the solder bath is guided, for example pumped, in the direction identified by the arrow in the inflow channel 18 in the direction of the end of the nozzle, such that a wave of liquid solder material forms at the end of the nozzle 17. The liquid solder material 16 at the end of the nozzle 17 may pass into the interspace 15 and onto the connection layers 6, 7 and wet the latter. Unused solder material 16 may be returned to the solder bath via the outflow channel 19. The nozzle 17 may be led circumferentially around the substrate 2, with the result that a circumferential solder layer 5 is formed when the solder material 16 has cooled. On account of the comparatively small solder wave, heat is introduced into the connection partners only very locally and so the risk of heat-governed damage to the functional region 3 is reduced.

The connection of the substrate 2 to the cover 4 by means of solder material 16 introduced into the connection region in liquid form is advantageous compared with a method in which the solder material is introduced as a paste, since energy- and thus heat-intensive steps for melting the solder material are obviated.

Bath soldering or dip soldering may also be used, of course, instead of selective wave soldering for the connection.

It goes without saying that features of different exemplary embodiments may be combined with one another, insofar as they are not mutually exclusive. Moreover, features from the general part of the description may be used for the exemplary embodiments, and vice versa.

This patent application claims the priority of the German patent application DE 102013110174.7 of Sep. 16, 2013, the disclosure content of which is hereby explicitly incorporated by reference in the present application.

The disclosure is not restricted by the description of the exemplary embodiments. Rather, the invention encompasses any novel feature and also any combination of features, which in particular includes any combination of features in the patent claims, even if this feature or this combination itself is not explicitly specified in the patent claims or exemplary embodiments.

1. An electronic component comprising
a substrate, on which an organic electronic functional region is arranged, and
a cover extending over the electronic functional region, wherein
the cover is connected to the substrate by means of an electrically conductive solder layer.

2. The electronic component according to claim 1, wherein
a) between the solder layer and the cover or
b) between the solder layer and the substrate,
a connection layer is arranged, to which the solder layer is connected.

3. The electronic component according to claim 2, wherein the connection layer is arranged between the solder layer and the substrate, and a further connection layer is arranged between the solder layer and the cover, wherein the solder layer is arranged between the two connection layers and is connected to the respective connection layer.

4. The electronic component according to claim 1,
wherein the solder material of the solder layer connects with the connection layer better than with the material that is offered on that side of the connection layer which faces away from the solder layer.

5. The electronic component according to claim 1,
wherein the connection layer is embodied in an electrically conductive fashion.

6. The electronic component according to claim 1,
wherein the solder material of the solder layer is a soft solder, and
wherein the material of the connection layer is copper.

7. The electronic component according to claim 1,
wherein the solder layer is impermeably connected to the connection layer and wherein the connection layer is impermeably connected respectively to the cover or the substrate, respectively.

8. The electronic component according to claim 1,
wherein one, an arbitrarily selected plurality or the totality of the following elements is embodied in such a way that the respective element,
the plurality of elements or the totality of the elements is part of an encapsulation of the functional region: solder layer, connection layer, cover, substrate.

9. The electronic component according to claim 1,
wherein the solder layer is electrically conductively connected to the electronic functional region.

10. The electronic component according to claim 1,
wherein an electrically insulating layer is arranged between the substrate and the solder layer.

11. The electronic component according to claim 10,
wherein the electrically insulating layer has anti-adhesion properties with respect to the solder material of the solder layer.

12. The electronic component according to claim 10,
wherein the electrically insulating layer extends over the electronic functional region.

13. The electronic component according to claim 1,
wherein the solder layer is arranged besides the functional region as seen in a plan view of the electronic functional region.

14. The electronic component according to claim 1,
wherein the connection layer extends over the electronic functional region.

15. The electronic component according to claim 1,
wherein a free space is formed between the electronic functional region and the cover, and a protection layer is arranged between the free space and the electronic functional region.

16. The electronic component according to claim 1,
wherein an adhesion promoting layer is arranged between the electronic functional region and the cover, said adhesion promoting layer being connected to the cover.

17. A method for producing an electronic component, comprising the following steps:
providing a substrate, on which an organic electronic functional region is arranged;
providing a cover;
arranging the cover and the substrate relative to one another in such a way that the cover extends over the electronic functional region and an interspace is formed between the substrate and the cover;
introducing a liquid solder material into the interspace, such that the interspace is filled with liquid solder material in places;
hardening the solder material in order to form a solder layer, by means of which the cover is connected to the substrate;
completing the component.

18. An electronic component comprising
a substrate, on which an organic electronic functional region is arranged, and
a cover extending over the electronic functional region, wherein
the cover is connected to the substrate by means of an electrically conductive solder layer,
between the solder layer and the cover or
between the solder layer and the substrate,
a connection layer is arranged, to which the solder layer is connected,
the solder material of the solder layer connects with the connection layer better than with the material that is offered on that side of the connection layer which faces away from the solder layer, and
the connection layer extends over the electronic functional region.

19. An electronic component comprising
a substrate, on which an organic electronic functional region is arranged, and
a cover extending over the electronic functional region, wherein the cover is connected to the substrate by means of an electrically conductive solder layer, and wherein the electrically conductive solder layer participates in the electrical contacting of the electronic component.
